(19) United States
(12) Patent Application Publication
(10) Pub. No.: US 2024/0222203 A1
(43) Pub. Date: Jul. 4, 2024

(54) METHOD FOR TRIMMING THE LIGHT SENSITIVITY OF A PHOTOTRANSISTOR

(71) Applicant: VISHAY SEMICONDUCTOR GMBH, Heilbronn (DE)

(72) Inventors: Manuel SCHMIDT, Waghäusel (DE); Dennis NOLL, Vaihingen a. d. Enz (DE); Kevin CROMWELL, Heilbronn (DE)

(21) Appl. No.: 18/557,843

(22) PCT Filed: Mar. 18, 2022
(86) PCT No.: PCT/EP2022/057166

§ 371 Date: Oct. 27, 2023

(30) Foreign Application Priority Data
Apr. 28, 2021 (DE) 10 2021 110 886.1

(51) Int. Cl. H01L 21/66; H01L 31/0224; H01L 31/11; H01L 31/18

(52) U.S. Cl. CPC H01L 22/26; H01L 31/022408; H01L 31/1105; H01L 31/186

(57) ABSTRACT

A method of trimming the light sensitivity of phototransistors that are produced in a wafer-based semiconductor process is disclosed. The phototransistors each have a rear-side collector, a base embedded in the collector, an emitter embedded in the base, and a front-side metallization that includes at least one bond pad for the emitter, and in particular a trimming structure. The regions of the front-side covered by the metallization define a light-insensitive area of the respective phototransistor, and the metal-free regions of the front-side define a light-sensitive area of the respective phototransistor. The method includes the steps of measuring the collector-emitter current of the phototransistors, and changing, in particular increasing, the size of the light-sensitive area by changing the size of the area covered by the metallization, in particular by removing at least a part of the trimming structure, in dependence on the measured collector-emitter current.

The invention relates to a method of trimming the light sensitivity of phototransistors that are produced in a wafer-based semiconductor process and that each have a rear-side collector, a base embedded in the collector, an emitter embedded in the base, and a front-side metallization.

In a phototransistor, the base-collector transition acts as a photodiode that generates a photocurrent when light is incident and when a collector-emitter voltage is applied, said photocurrent being amplified by the current gain factor of the transistor to the collector-emitter current that is also designated as collector current. The current gain factor and thus the collector current depend mainly on the implantation depths of the base and the emitter, which jointly define the base width, and on the doping concentrations of the base and the emitter. In the production of phototransistors, it is therefore crucial to make the semiconductor process as stable as possible.

Nevertheless, process variations of these parameters, in particular from wafer to wafer, cannot be completely avoided. These process variations lead to corresponding variations in the current gain factors and thus in the light sensitivity of the phototransistors produced and consequently to the problem that the phototransistors are not in a desired binning range of the collector current for which they were produced, but in another binning range, in particular an adjacent binning range, for which there may be no demand. The yield of usable phototransistors hereby decreases, whereby the production costs increase.

It is therefore the underlying object of the invention to provide a possibility of increasing the yield of phototransistors that lie within the respective desired range for the collector current.

This object is satisfied by a method having the features of independent claim 1, namely by a method of trimming the light sensitivity of phototransistors that are produced in a wafer-based semiconductor process and that each have a rear-side collector, a base embedded in the collector, an emitter embedded in the base, and a front-side metallization that comprises at least one bond pad for the emitter and in particular a trimming structure, wherein the regions of the front side covered by the metallization define a light-insensitive area of the respective phototransistor and the metal-free regions of the front side define a light-sensitive area of the respective phototransistor, wherein the method comprises the steps: measuring the collector-emitter current of the phototransistors; and changing, in particular increasing, the size of the light-sensitive area by changing the size of the area covered by the metallization, in particular by removing at least a part of the trimming structure, in dependence on the measured collector-emitter current.

In accordance with the invention, the increase in the yield of phototransistors that lie in the respective desired range for the collector current is not achieved by reducing the process variations in the semiconductor process, but by trimming the light sensitivity of the phototransistors. The trimming takes place as a so-called post-processing, and indeed such that the size of the area covered by the metallization and thus the size of the light-sensitive area are changed. A trimming of the light sensitivity of the phototransistors via a post-processing temperature treatment to cause a diffusion of the emitter or of the base and thus a change of the collector current is, in contrast, not possible since the metallization of the phototransistors cannot withstand the high temperatures required for this purpose.

The metallization preferably comprises a trimming structure, wherein the changing of the size of the area covered by the metallization takes place by removing at least a part of the trimming structure. In general, the changing of the size of the area covered by the metallization is, however, also possible by depositing additional metal in the metal-free regions, for example, by means of the so-called lift-off process. However, compared to the removal of at least a part of a trimming structure, the deposition of additional metal in the metal-free regions is more complex and/or expensive.

To determine the extent to which the size of the light-sensitive area has to be changed, the collector-emitter current of the phototransistors is measured beforehand. The extent of the change of the size of the light-sensitive area is then determined based on the measured collector-emitter current. The measurement of the collector-emitter current takes place under defined measurement conditions. In general, the measured collector-emitter current can be the measurement value of a single measurement at a single phototransistor. However, the measured collector-emitter current is preferably a current value calculated from a plurality of measurements at different phototransistors, which are in particular arranged distributed over the wafer, in particular a mean value, during whose calculation outliers, which are in particular due to defects in the processing, can remain out of consideration.

Provision is in particular made that the removal of at least a part of the trimming structure comprises that the area of the trimming structure is reduced in dependence on the measured collector-emitter current by a trimming area associated with the measured collector-emitter current, with, in particular exactly three, mutually adjoining measurement value ranges for the collector-emitter current being provided with which trimming areas of different sizes are associated, with the size of the respective trimming area being greater, the smaller the collector-emitter currents falling into the respective measurement value range are.

This does not rule out that, from a certain limit value onward, the area of the trimming structure is not reduced, but is maintained, i.e. that the corresponding measurement value range has a trimming area of 0%. The more measurement ranges are provided, the finer the light sensitivity of the phototransistors can be trimmed.

In accordance with a preferred embodiment of the invention, the area of the trimming structure is reduced by a predefined desired value trimming area if the measured collector-emitter current lies within a predefined desired value range which is adjoined below and above by at least one further measurement value range in each case. The method is therefore set such that the trimming structure is reduced by the predefined desired value trimming area when no process variations have occurred in the semiconductor process. In other words, if no process variations have occurred during the production, the phototransistors are initially detuned and first have to be adapted via the reduction of the trimming structure by the predefined desired value trimming area. This approach makes it possible that, if process variations occur, corresponding deviations of the current gain factor of the phototransistors can be compensated in both directions, i.e. both in the direction of a too low current gain factor and in the direction of a too high current gain factor. The predefined desired value trimming area can in particular amount to 50% of the area of the trimming structure.

It is preferred if the trimming area for the measurement value range that lies below the desired value range or the measurement value range that lies the furthest below the desired value range amounts to 100% of the area of the trimming structure, i.e. that the trimming structure is completely removed. The greatest possible change in the current gain factor of the phototransistors can hereby be achieved.

It is furthermore preferred if the trimming area for the measurement value range that lies above the desired value range or the measurement value range that lies the furthest above the desired value range amounts to 0% of the area of the trimming structure, i.e. that the area of the trimming structure is not reduced, but is maintained. On the one hand, the greatest possible change in the current gain factor of the phototransistors can hereby be achieved and, on the other hand, the effort for the removal of a part of the trimming structure can hereby be saved.

In accordance with a preferred embodiment, the removal of at least a part of the trimming structure comprises that a photoresist is applied at the front side to the phototransistors in dependence on the measured collector-emitter current and is structured using a photomask and then the regions of the respective trimming structure that are not covered by the structured photoresist are removed, in particular by a wet chemical etching or a dry etching, wherein in particular the remaining metallization is covered by the structured photoresist. This is an easy-to-implement removal process for the trimming structure or the part thereof.

In this respect, provision is in particular made that the photomask is selected from a set of different photomasks, in particular from a set of exactly two different photomasks, that differ in the area of their regions that are permeable to light in the case of a positive resist or impermeable to light in the case of a negative resist, said regions being imaged onto the photoresist in the regions of the trimming structure that are not covered by the structured photoresist, in particular in the respective aforementioned trimming area. Exactly two different photomasks can in particular be present when exactly three aforementioned measurement value ranges are provided and a trimming area of 0% is associated with the measurement value range that lies above the aforementioned desired value range.

The measurement of the collector-emitter current of the phototransistors can, in accordance with a variant, comprise that the respective phototransistor is illuminated and the respective base is unconnected or connected. In accordance with another variant, the measurement of the collector-emitter current of the phototransistors can, however, also comprise that the respective base is connected and the respective phototransistor is unilluminated or illuminated. The measurement takes place under defined measurement conditions, for example, at a collector-emitter voltage of 5 V, and/or at an intensity of illumination of 1 mW/cm2, and/or at a wavelength of 950 nm. The aforementioned desired value range in the case of a measurement in accordance with the one variant will typically be different from the desired value range in the case of a measurement in accordance with the other variant.

The metallization can have as structures the bond pad for the emitter and the trimming structure and, optionally, additionally a bond pad for the base and/or at least one frame-like structure for shielding electrical fields, with the trimming structure being formed separately from the other structure or structures or being connected to the or at least one of the other structures, in particular to the bond pad for the base. The respective frame-like structure is preferably connected to the bond pad of the emitter.

The invention further relates to a phototransistor, namely a trimmed phototransistor, obtainable by a method such as described above, and to a phototransistor that is produced in a wafer-based semiconductor process and whose light sensitivity can be trimmed and that has a rear-side collector, a base embedded in the collector, an emitter embedded in the base, and a front-side metallization that comprises at least one bond pad for the emitter and in particular a trimming structure, wherein the regions of the front side covered by the metallization define a light-insensitive area of the phototransistor and the metal-free regions of the front side define a light-sensitive area of the phototransistor, wherein the collector-emitter current can be measured, and wherein the size of the light-sensitive area can be changed, in particular can be increased, in dependence on the measured collector-emitter current by changing the size of the area covered by the metallization, in particular by removing at least a part of the trimming structure.

The invention furthermore relates to an optocoupler comprising an optical transmitter and an optical receiver, wherein the optical receiver is configured as a phototransistor, such as described above, and to the use of a phototransistor, such as described above, for measuring the ambient light brightness, in particular for setting the brightness of an instrument panel lighting and/or of an interior lighting of a motor vehicle.

Further advantageous embodiments of the invention are described in the dependent claims, in the description of the Figures, and in the drawing. Preferred embodiments explained with respect to the method in accordance with the invention apply accordingly to the phototransistor in accordance with the invention.

The invention will be described in the following by way of example with reference to the drawing. There are shown:

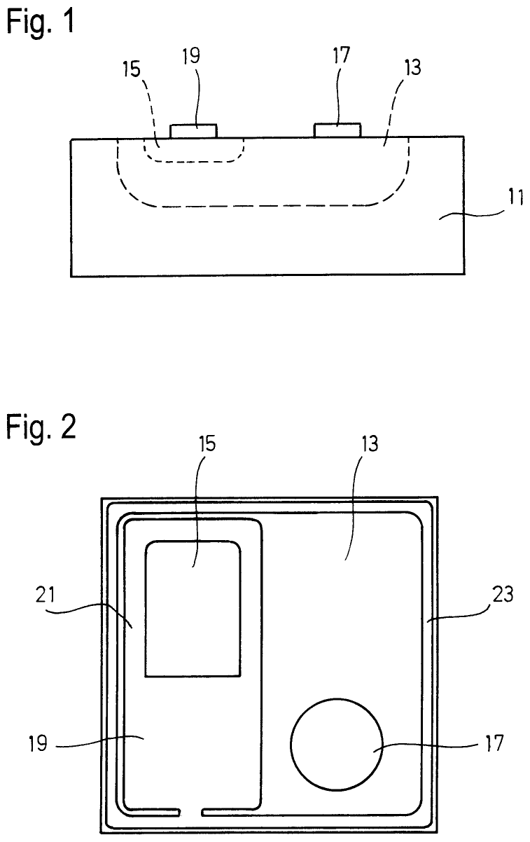

FIG. 1 a phototransistor in a cross-section;

FIG. 2 a phototransistor in a plan view;

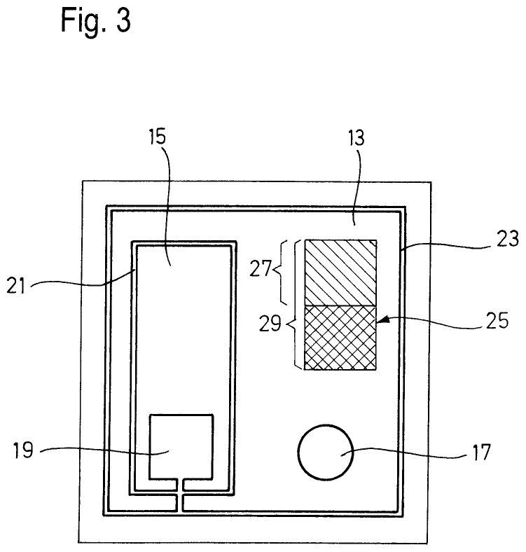

FIG. 3 a phototransistor in accordance with a first embodiment that is used in a method in accordance with the invention; and

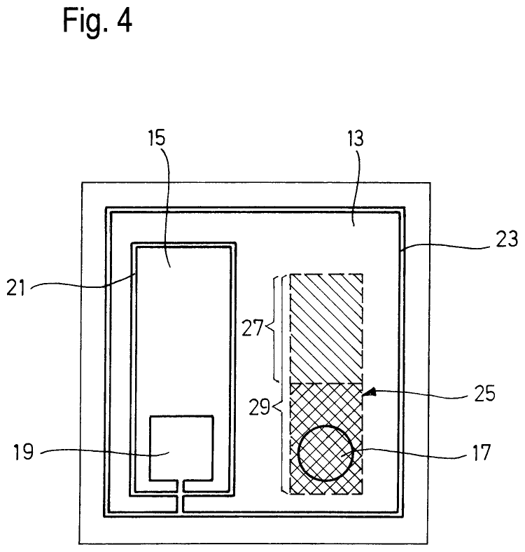

FIG. 4 a phototransistor in accordance with a second embodiment that is used in a method in accordance with the invention.

The phototransistor shown in FIG. 1 was produced in a wafer-based semiconductor process and comprises a rear-side, weakly n-doped (n−) collector 11, a p-doped (p) base 13 embedded in the collector 11, and a strongly n-doped (n+) emitter 15 embedded in the base 13. The rear side of the phototransistor is provided over the whole area with a metal contact, not shown, for the electrical connection of the collector 11. A bond pad 17 for the base 13 and a bond pad 19 for the emitter 15, which are both part of the metallization of the phototransistor composed of aluminum, are applied to the front side of the phototransistor. Furthermore, the base 13 and the emitter 15 are covered by a nitride layer, which is not shown and which acts as an anti-reflective layer for an incident illumination, in the regions in which they are not provided with the respective bond pad 17, 19.

As can be seen from FIG. 2, in addition to the two bond pads 17, 19 for the base 13 and the emitter 15, the metallization comprises two frame-like structures 21, 23 for shielding electrical fields. The two frame-like structures 21, 23 are each connected to the bond pad 19 of the emitter 15 that is connected to ground in the operation of the phototransistor. The first frame structure 21 extends along the boundaries of the region of the emitter 15 and the second frame structure 23 surrounds both the region of the base 13 and the region of the emitter 15.

The regions of the front side of the phototransistor covered by the metallization form a light-insensitive area of the phototransistor and the metal-free regions form a light-sensitive area of the phototransistor. The light sensitivity of the phototransistor can be set via the portion of the light-sensitive area in the total area of the front side of the phototransistor, i.e. via the portion of the front side that is not covered by the metallization: The larger the uncovered area, the greater the light sensitivity.

To be able to trim the light sensitivity of the phototransistor, the metallization has a trimming structure 25 such as shown in FIGS. 3 and 4. The trimming structure 25 is located above the region of the base 13, but can generally also be arranged above the region of the emitter 15. The aforementioned nitride layer, not shown, is located between the base 13 and the trimming structure 25. In the embodiment in accordance with FIG. 3, the trimming structure 25 is formed separately from the remaining metallization; in the embodiment in accordance with FIG. 4, the trimming structure 25 is connected to the bond pad 17 for the base 13. In the phototransistors shown in FIGS. 3 and 4, the size of the light-sensitive area can be increased in that at least a part of the area of the trimming structure 25 is removed.

The removal of at least a part of the area of the trimming structure 25 takes place by means of a photomask step in which a photoresist is applied at wafer level to the metallizations of the phototransistors and is structured by means of a photomask such that the parts of the area of the trimming structures 25 to be removed are not covered by the structured photoresist so that they can be removed by means of a metal etching step. The remaining metallization is in this respect covered by the structured photoresist and is thus protected against the metal etching step.

The trimming of the light sensitivity of the phototransistors is necessary when process variations occur during the production that cause the light sensitivity of the phototransistors to not lie in an expected range, but outside it. Whether this is the case, i.e. whether a trimming is required, can be determined in that the collector-emitter current of the phototransistors that corresponds to the light sensitivity is measured. This measurement can take place in the case of just an electrical connection or an optoelectrical connection of the transistors.

To be able to compensate process variations in both directions, i.e. both too large and too small current gains, the phototransistor does not have the current gain for which it is specified when the trimming structure 25 is completely present, but when the trimming structure 25 is reduced by 50%. Accordingly, the trimming structure 25 is reduced by a desired value trimming area 27 that amounts to 50% of the area of the trimming structure 25, i.e. is removed by half, by means of a first photomask when the measured collector-emitter current lies within a predefined desired value range for which the phototransistor is specified. If the measured collector-emitter current is too large and lies above the desired value range, the trimming structure 25 is not reduced, but is maintained in its original size. The size of the trimming area then amounts to 0%. If the measured collector-emitter current is too small and lies below the desired value range, the trimming structure 25 is reduced by a trimming area 29 that amounts to 100% of the area of the trimming structure 25, i.e. is completely removed, wherein a second photomask is then selected that differs accordingly from the first photomask.

In this way, the size of the light-sensitive area of the phototransistors can be changed at wafer level in dependence on the measured collector-emitter current and a trimming of the light sensitivity of the phototransistors can thereby be achieved. In another respect, the trimming areas can also have values other than the aforementioned values and more than the two aforementioned photomasks can be used to enable a finer setting of the light sensitivity of the phototransistors.

1-14. (canceled)

15. A method of trimming light sensitivity of phototransistors that are produced in a wafer-based semiconductor process and that each have a rear-side collector, a base embedded in the collector, an emitter embedded in the base, and a front-side metallization that comprises at least one bond pad for the emitter, wherein regions of the front side covered by the metallization define a light-insensitive area of the respective phototransistor and metal-free regions of the front side define a light-sensitive area of the respective phototransistor, wherein the method comprises the steps of:
measuring a collector-emitter current of the phototransistors; and
changing a size of the light-sensitive area by changing a size of the area covered by the metallization in dependence on the measured collector-emitter current.

16. The method in accordance with claim 15, wherein the front-side metallization comprises a trimming structure, wherein changing the size of the light-sensitive area by changing the size of the area covered by the metallization comprises increasing the size of the light-sensitive area by changing the size of the area covered by the metallization by removing at least a part of the trimming structure.

17. The method in accordance with claim 16, wherein removing at least a part of the trimming structure comprises that the area of the trimming structure is reduced in dependence on the measured collector-emitter current by a trimming area associated with the measured collector-emitter current, with mutually adjoining measurement value ranges for the collector-emitter current being provided with which trimming areas of different sizes are associated, with the size of the respective trimming area being greater, the smaller the collector-emitter currents falling into the respective measurement value range are.

18. The method in accordance with claim 17, wherein the area of the trimming structure is reduced by a predefined desired value trimming area if the measured collector-emitter current lies within a predefined desired value range which is adjoined below and above by at least one further measurement value range in each case.

19. The method in accordance with claim 18, wherein the predefined desired value trimming area amounts to 50% of the area of the trimming structure.

20. The method in accordance with claim 18, wherein the trimming area for the measurement value range that lies below the desired value range or the measurement value range that lies the furthest below the desired value range amounts to 100% of the area of the trimming structure.

21. The method in accordance with claim 18, wherein the trimming area for the measurement value range that lies above the desired value range or the measurement value range that lies the furthest above the desired value range amounts to 0% of the area of the trimming structure.

22. The method in accordance with claim 16, wherein removing at least a part of the trimming structure comprises that a photoresist is applied at the front side to the phototransistors in dependence on the measured collector-emitter current and is structured using a photomask and then regions of the respective trimming structure that are not covered by the structured photoresist are removed.

23. The method in accordance with claim 22, wherein the photomask is selected from a set of different photomasks that differ in the area of their respective regions that are permeable to light in a case of a positive resist or impermeable to light in a case of a negative resist, said regions being imaged onto the photoresist in regions of the trimming structure that are not covered by the structured photoresist.

24. The method in accordance with claim 15, wherein the measurement of the collector-emitter current of the phototransistors comprises that the respective phototransistor is illuminated and the respective base is unconnected or connected, or in that the measurement of the collector-emitter current of the phototransistors comprises that the respective base is connected and the respective phototransistor is unilluminated or illuminated.

25. The method in accordance with claim 15, wherein the metallization has as structures a bond pad for the emitter and a trimming structure and, optionally, additionally a bond pad for the base and/or at least one frame-like structure for shielding electrical fields, with the trimming structure being formed separately from the other structure or structures or being connected to the or at least one of the other structures.

26. The method in accordance with claim 17, wherein the mutually adjoining measurement value ranges consist of three mutually adjoining value ranges.

27. The method in accordance with claim 22, wherein regions of the respective trimming structure that are not covered by the structured photoresist are removed by a wet chemical etching or a dry etching.

28. The method in accordance with claim 23, wherein the photomask is selected from a set consisting of two different photomasks.

29. The method in accordance with claim 25, wherein the trimming structure is connected to the bond pad for the base.

30. A phototransistor made according to the method of claim 15.

31. A phototransistor that is produced in a wafer-based semiconductor process and whose light sensitivity can be trimmed and that has a rear-side collector, a base embedded in the collector, an emitter embedded in the base, and a front-side metallization that comprises at least one bond pad for the emitter, wherein the regions of the front side covered by the metallization define a light-insensitive area of the phototransistor and the metal-free regions of the front side define a light-sensitive area of the phototransistor, wherein the collector-emitter current can be measured, and wherein the size of the light-sensitive area can be changed in dependence on the measured collector-emitter current by changing the size of the area covered by the metallization.

32. The phototransistor in accordance with claim 31, wherein the front-side metallization comprises a trimming structure, wherein changing the size of the light-sensitive area by changing the size of an area covered by the metallization comprises increasing the size of the light-sensitive area by changing the size of the area covered by the metallization by removing at least a part of the trimming structure.

33. The phototransistor in accordance with claim 31, wherein the phototransistor is configured for use in measuring an ambient light brightness.

34. The phototransistor in accordance with claim 33, wherein the phototransistor is further configured for setting the brightness of an instrument panel lighting and/or of an interior lighting of a motor vehicle.

35. An optocoupler comprising an optical transmitter and an optical receiver, wherein the optical receiver is configured as a phototransistor in accordance with the claim 31.
